(19) United States
(12) Patent Application Publication
(10) Pub. No.: US 2007/0064832 A1
(43) Pub. Date: Mar. 22, 2007

(54) Frequency ramp modulation

(76) Inventor: Michael L. Frank, Menlo Park, CA (US)

Correspondence Address: AVAGO TECHNOLOGIES, LTD., P.O. BOX 1920, DENVER, CO, 80201-1920, US

(21) Appl. No.: 11/231,377

(22) Filed: Sep. 21, 2005

(51) Int. Cl. H03K 9/06

(52) U.S. Cl. 375/271

(57) ABSTRACT

A frequency ramp modulation technique that encodes information using frequency ramps in a transmit signal. Frequency ramp modulation according to the present teachings may be employed in a communication system that includes a narrow band receiver to maintain communication even as the pass band of the narrow band receiver drifts with temperature or other factors.

### BACKGROUND

A variety of modulation techniques exist that may be used in a communication system to encode information into a transmit signal. Examples of prior modulation techniques include amplitude modulation (AM) and frequency modulation (FM). Other prior modulation techniques include techniques that may combine amplitude and phase modulation, e.g. quadrature amplitude modulation (QAM), GPSK, etc.

It may be desirable in a communication system to employ a receiver having a relatively narrow receive band. For example, a narrow receive band may reduce the power consumption of a receiver. In addition, a narrow receive band may enable an increase in the sensitivity of a receiver.

Unfortunately, prior modulation techniques may have limited applicability to a communication system that includes a narrow band receiver. For example, the center frequency of the pass band of a narrow band receiver may drift with temperature. In addition, manufacturing variation in the components of a narrow band receiver may cause variation in the center frequency of its pass band. As a consequence, the pass band of a narrow band receiver may drift outside of the transmit band of a transmitter that employs a prior modulation technique, thereby breaking the communication link between the transmitter and the narrow band receiver.

### SUMMARY OF THE INVENTION

A frequency ramp modulation technique is disclosed that encodes information using frequency ramps in a transmit signal. Frequency ramp modulation according to the present teachings may be employed in a communication system that includes a narrow band receiver to maintain communication even as the pass band of the narrow band receiver drifts with temperature or other factors.

Other features and advantages of the present invention will be apparent from the detailed description that follows.

### BRIEF DESCRIPTION OF THE DRAWINGS

The present invention is described with respect to particular exemplary embodiments thereof and reference is accordingly made to the drawings in which:

FIG. 1 shows a communication system according to the present teachings;

FIG. 2 illustrates an example series of continuously varying frequency ramps in the transmit signal;

FIG. 3 illustrates an example series of step-wise frequency ramps in the transmit signal;

FIG. 4 illustrates a transmitter according to the present teachings;

FIG. 5 illustrates a receiver according to the present teachings.

### DETAILED DESCRIPTION

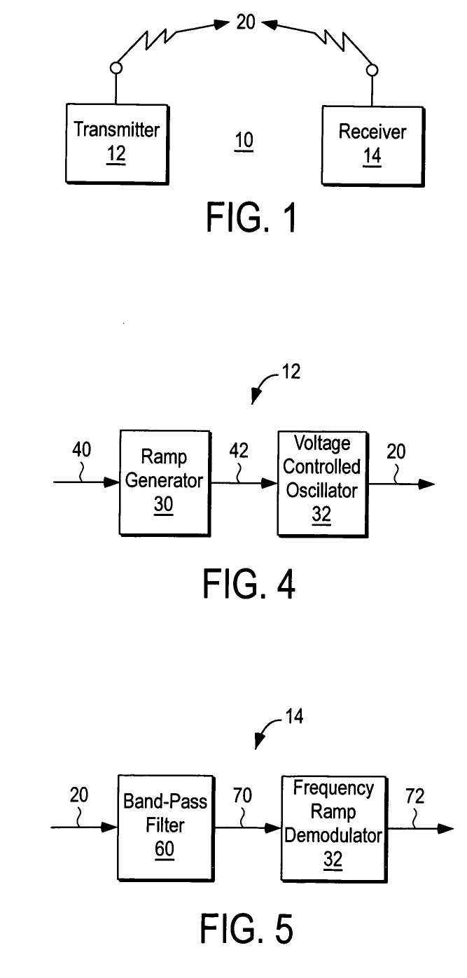

FIG. 1 shows a communication system 10 according to the present teachings. The communication system 10 includes a transmitter 12 and a receiver 14. The transmitter 12 generates a transmits signal 20. The transmit signal 20 carries information that is indicated by a frequency ramp in the transmit signal 20. The receiver 14 receives the transmit signal 20 and obtains the information carried in the transmit signal 20 by detecting the frequency ramp in the transmit signal 20.

The frequency ramp in the transmit signal 20 may be an increase in a frequency of the transmit signal over time. The frequency ramp in the transmit signal 20 may be a decrease in a frequency of the transmit signal 20 over time. The frequency ramp in the transmit signal 20 may be a step-wise increase or decrease in a frequency of the transmit signal over time.

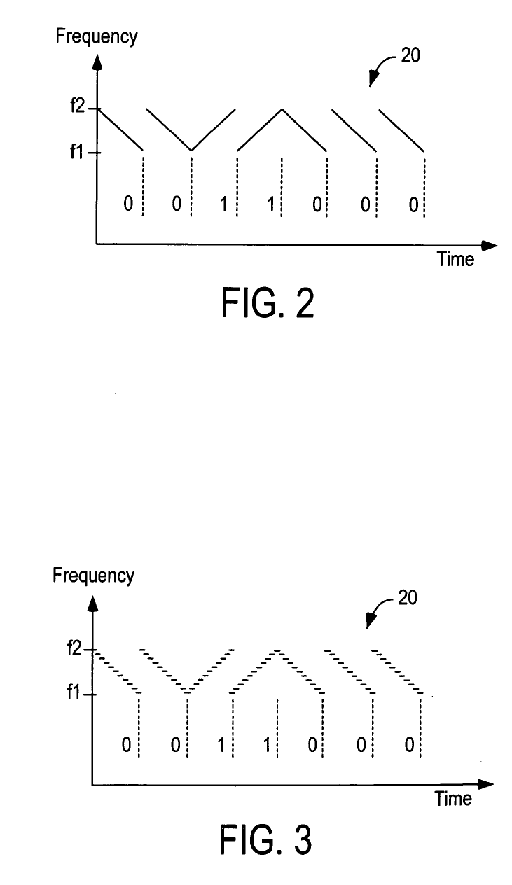

FIG. 2 illustrates an example series of continuously varying frequency ramps in the transmit signal 20. In this example, a falling ramp in a frequency of the transmit signal 20 indicates a “0” of information and a rising ramp in a frequency of the transmit signal 20 indicates a “1” of information. The series of ramps shown encodes the information “0011000” in the transmit signal 20.

FIG. 3 illustrates an example series of step-wise frequency ramps in the transmit signal 20. In this example, a step-wise decrease in a frequency of the transmit signal 20 indicates a “0” of information and a step-wise increase in a frequency of the transmit signal 20 indicates a “1” of information. The series of step-wise ramps shown encodes the information “0011000” in the transmit signal 20.

FIG. 4 illustrates the transmitter 12 in one embodiment. The frequency ramp modulator in the transmitter 12 in this embodiment includes a ramp generator 30 and a voltage controlled oscillator 32.

The ramp generator 30 generates a ramp signal 42 in response to an information signal 40. For example, the information signal 40 may carry digital information including a series of 0's and 1's to be carried via the transmit signal 20. In an embodiment corresponding to the information coding illustrated in FIG. 2, the ramp generator 40 generates a rising ramp in the amplitude of the ramp signal 42 in response to a “1” in the information signal 40 and a falling ramp in the amplitude of the ramp signal 42 in response to a “0” in the information signal 40. The ramp generator 30 may generate triangle waveform ramps or some other form of linear ramp or a non-linear monotonic ramp.

The voltage controlled oscillator 32 generates the transmit signal 20 at a frequency that is determined by a magnitude of the ramp signal 42. A rising ramp in the magnitude of the ramp signal 42 causes a rising ramp in the frequency of the transmit signal 20 and a falling ramp in the magnitude of the ramp signal 42 causes a falling ramp in the frequency of the transmit signal 20.

FIG. 5 illustrates the receiver 14 in one embodiment. The receiver 14 in this embodiment includes a band-pass filter 60 and a frequency ramp demodulator 62. The band-pass filter 60 controls the receive band of the receiver 14. In some embodiments, the receiver 14 may not include the band-pass filter 60 or may include another type of filter.

The band-pass filter 60 generates a filter output signal 70 by filtering out frequency components of the transmit signal 20 that do not fall within a pass band of the band-pass filter 60. The range of frequencies of the frequency ramps in the transmit signal 20, between f1 and f2, is selected in response to the pass band of the band-pass filter 60 and the likely drift in the center frequency of the pass band of the band-pass filter 60. The range between f1 and f2 is selected so that some part of the frequency ramps between f1 and f2 will overlap the pass band of the band-pass filter 60 even after variation in the center frequency of the band-pass filter 60, thereby maintaining communication between the transmitter 12 and the receiver 14.

The frequency ramp demodulator 62 recovers information from the filter output signal 70 by detecting rising and falling frequency ramps in the filter output signal 70. In an embodiment corresponding to the information coding illustrated in FIG. 2, the frequency ramp demodulator 62 generates a “1” in an information signal 72 in response to a rising ramp in a frequency of the filter output signal 70 and generates a “0” in the information signal 72 in response to a falling ramp in a frequency of the filter output signal 70.

The foregoing detailed description of the present invention is provided for the purposes of illustration and is not intended to be exhaustive or to limit the invention to the precise embodiment disclosed. Accordingly, the scope of the present invention is defined by the appended claims.

What is claimed is:

1. A communication system, comprising:
transmitter that generates a transmits signal such that an information carried in the transmit signal is indicated by a frequency ramp in the transmit signal;
receiver that obtains the information from the transmit signal by detecting the frequency ramp.

2. The communication system of claim 1, wherein the frequency ramp comprises an increase in a frequency of the transmit signal over time.

3. The communication system of claim 1, wherein the frequency ramp comprises a decrease in a frequency of the transmit signal over time.

4. The communication system of claim 1, wherein the frequency ramp comprises a step-wise increase in a frequency of the transmit signal over time.

5. The communication system of claim 1, wherein the frequency ramp comprises a step-wise decrease in a frequency of the transmit signal over-time.

6. The communication system of claim 1, wherein the transmitter includes a frequency-ramp modulator comprising:
ramp generator that generates a ramp signal in response to the information;
voltage controlled oscillator that generates the transmit signal in response to the ramp signal.

7. The communication system of claim 1, wherein the receiver includes a frequency ramp demodulator that recovers the information from the transmit signal.

8. The communication system of claim 1, wherein the receiver comprises:
filter that provides a filter output signal by filtering the transmit signal;
frequency ramp demodulator that recovers the information from the filter output signal.

9. The communication system of claim 8, wherein a frequency range of the transmit signal is selected in response to a variability in a pass band of the filter.

10. A method for communication, comprising:
generating a transmits signal such that an information carried in the transmit signal is indicated by a frequency ramp in the transmit signal;
obtaining the information from the transmit signal by detecting the frequency ramp.

11. The method of claim 10, wherein generating a transmits signal includes generating the frequency ramp having an increase in a frequency of the transmit signal over time.

12. The method of claim 10, wherein generating a transmits signal includes generating the frequency ramp having a decrease in a frequency of the transmit signal over time.

13. The method of claim 10, wherein generating a transmits signal includes generating the frequency ramp having a step-wise increase in a frequency of the transmit signal over time.

14. The method of claim 10, wherein generating a transmits signal includes generating the frequency ramp having a step-wise decrease in a frequency of the transmit signal over time.

15. The method of claim 10, wherein generating a transmits signal comprises:
generating a ramp signal in response to the information;
generating the transmit signal in response to the ramp signal.

16. The method of claim 10, wherein obtaining comprises:
generating a filter output signal by filtering the transmit signal;
recovering the information from the filter output signal.

17. The method of claim 16, further comprising selecting a frequency range of the transmit signal in response to a variability in a pass band of the filter output signal.
